(19) United States
(12) Patent Application Publication
(10) Pub. No.: US 2022/0117092 A1
(43) Pub. Date: Apr. 14, 2022

(54) CONTINUOUS ETCHING SYSTEM

(71) Applicants: Jainil SHAH, Nadiad, Gujarat (IN); Vimal SHAH, Nadiad, Gujarat (IN)

(72) Inventors: Jainil SHAH, Nadiad, Gujarat (IN); Vimal SHAH, Nadiad, Gujarat (IN)

(21) Appl. No.: 17/268,839

(22) PCT Filed: Jul. 29, 2019
(86) PCT No.: PCT/IB2019/056437

§ 371 Date: Feb. 16, 2021

(30) Foreign Application Priority Data
Aug. 16, 2018 (IN) 201821030739

(51) Int. Cl. H05K 3/06; C23F 1/08; C23F 1/34

(52) U.S. Cl. CPC H05K 3/068; H05K 3/067; H05K 2203/0793; C23F 1/34; C23F 1/08

(57) ABSTRACT

The present invention relates to continuous etching system for copper etching in manufacturing of Printed Circuit Boards (PCB). The present invention more particularly relates to continuous etching system provides zero undercut, zero residue copper and non-corrosive surfaces on PCB with environmentally safe and efficient manner. The present invention provides continuous copper etching system in manufacturing of PCBs without pump or any machine force for flowing of etchant.

### FIELD OF INVENTION

The present invention relates to continuous etching system for copper etching in manufacturing of Printed Circuit Boards (PCBs). The present invention more particularly relates to provide zero undercut, zero residue copper and non-corrosive surfaces on PCBs with environmentally safe and efficient manner by using continuous etching system.

### BACKGROUND OF INVENTION

Electronic equipment is primarily assembled from components soldered on to printed circuit boards (PCBs). A large quantity of copper is used nowadays in the manufacture of these PCBs. Advanced electronics, e.g. computers; require complicated PCBs and the manufacture of these have led to the growth of a specialized industry.

PCB also known as Semiconductor Integrated circuit boards are thin plates usually of plastic and laminate and on which a lay out patterns are made with thin copper layer on one or both sides. PCB mechanically supports and electrically connects electronic components using conductive tracks, pads and other features etched from copper sheets laminated onto a non-conductive substrate. Components such as capacitors, resistors or active devices are generally soldered on the PCB.

Manufacturing of PCB goes through many processes including different kinds of etching for placing desired pattern of copper or for removing unwanted copper from the PCB or placing of tin on PCB or removing tin from the PCB. One of such process is Copper Etching to remove excess or unwanted copper from the PCB.

Copper etching is considerably important process in electronics industry, particularly in the fabrication of PCB. There are many ways to remove extra copper from the PCB plate, however, chemical etching also called as immersion etching is more commonly used, wherein after covering the desired lay-out part of copper with a protective layer (usually of protective plastic film or tin) copper etching is done to remove excess copper, by either dipping or covering PCB with etchant chemical (known as etchant bath) or through spray of chemical on PCB and the copper not protected by the protective sheet is then removed during etching. Heat and agitation can be applied to the bath to speed up the etching rate. The spray technique is also used wherein the to etchant is sprayed over the PCB. The chemical reaction between open or exposed copper and chemical etchant bath make the copper dissolve in the etchant bath and thereby it gets removes copper from PCB, while copper remains intact in the covered part of PCB.

The current method for copper etching in manufacturing of PCBs is feeding in the PCB's onto the rollers of the etching machine/etch chamber. Then, these PCBs are passed into the spray nozzles which are sprayed from upper and lower side. At a specific attained density the auto dosing pump adds specific/preset quantity of etchant and flushes specific/preset quantity of etchant upon the density is required for optimum etching parameters. To adjust the optimum and continuous etching, the auto dosing process has to constantly add etchant and constantly flush out used etchant continuously throughout the process where the copper etching takes place.

The auto dosing system has added benefits upon manual dosage system of etchant previously, i.e. clearing the floor, improving the inefficient etching parameters caused due to inaccurate fresh etchant addition into the etch chamber and inaccurate flushing of quantity of spent removed from the bath.

There are some disadvantages also of the auto dosing system. For example, when the new/fresh etchant is added and the old/spent etchant is flushed there is no accuracy of complete flushing of only the used etchant which in turns, also flushes some quantity of fresh unused quaintly of etchant which was just added into the bath; this makes highly inefficient use of fresh chemical causing huge losses to PCB manufacturers over etchant quantity usage.

Therefore, even the auto dosing system is not always accurate to maintain parameters in case of PCB boards of different copper thickness is added into the etch chamber. For example, if thickness of PCBs like 18 micron to 70 microns, then the auto dosing system is not able to add new etchant quantity more than preset and the PCB has to rework/etch again due to copper under issue. The under copper issue is increased when the PCB copper thickness varies in the etching machine. And also the auto dosing fails to cope up the quantity decision of new etchant addition into the machine.

Above problem can be solved by setting auto dosing according to thickness of PCBs by adding accurate new etchant but it fails in flushing exact quantity of used etchant which thus causing inaccurate parameters of the etch chamber bath. Further, this can also create serious issues like under etching, over retching and zig-zag track cuts of the copper tracks whilst etching process. Ultimately, the said problems lead to heavy PCB rejection at bare board testing process due to etching flaws.

Furthermore, due to the auto dosing system the spent etchant solution have fresh etchant added in some quantities which doesn't makes the spent etchant so highly accurate copper rich, which contains significant quantity of ammonia and chloride concentration in the spent etchant which can trigger in copper recovery due to high chloride salts due to the addition of strong new fresh ammonia while auto dosing process in the spent etchant.

Moreover, due to the auto-dosing inaccuracy this can maximum offer etching track reduction up to 2 mil which is the lowest for some high profile aerospace PCB and Teflon and RF PCB's too. This can also cause high usage of electricity constantly whenever the etchant machine is in use which consumes a considerable amount of electricity to run the auto dosing pump.

Keeping in view of above all disadvantages of existing etchant system, the present invention relates to provide highly efficient, economical, environment friendly etching system leads to yield of high accuracy PCB results. This makes greater industrial advancement in the sector of PCB manufacturing.

### RELATED PRIOR ARTS

U.S. Pat. No. 5,169,477 relates to an etching apparatus for forming circuit patterns on a printed circuit board comprises a conveyor for conveying printed circuit boards, a solvent pump for pumping etching solution, nozzles for spraying etching liquid or water on the printed circuit board, and a rinsing device for rinsing the surface of the printed circuit board.

US 20170243768 relates to the field of liquid crystal displays, and more particularly to an etching method of a glass substrate and a wet etching apparatus thereof.

WO 2015150448 relates to a process of oxidizing copper in a copper etching solution by using oxygen gas and/or air as an oxidizing agent.

WO 200768193 relates to a use of a metal aluminum recovery and recycling the spent ammonia-containing alkaline copper etchant method.

US 20120273462 relates to an etching device is provided, the etching device including a process chamber including an etchant, a structure configured to provide a laminar flow of the etchant, and a work-piece handler configured to move a work-piece through the laminar flow of the etchant along a predefined track.

US 20050183819 describes an etching system includes an etching chamber, an etchant solution tank connected with the etching chamber, a heater set in the tank, and a deionized water (DIW) adding device.

US20170110344 provides a wet etching apparatus to remove an etching liquid or an etching liquid crystal formed by the etching liquid at an inlet and outlet of the etching chamber, thus improving production efficiency and product quality.

U.S. Pat. No. 4,397,708 relates to an etching method and etching and etchant removal apparatus which includes two sets of fan spray nozzles located adjacent to the etching chamber and positioned to direct a spray at the work piece as the work piece exits the etching chamber.

U.S. Pat. No. 3,689,333 discloses an etching machine includes an etchant tank housing an etchant spray system and a workpiece support system wherein the spray system includes at least one upright rotatable tubular body formed from coaxial cylinders closed at the upper end to provide a spray chamber. The lower end of the tubular body is immersed in the etchant bath and helical vanes within the spray chamber deliver etchant under pressure through the spray apertures as the tubular body rotates.

U.S. Pat. No. 2,669,048 describes an etching machine for etching printing plates, the combination of a tank adapted to contain a liquid etching composition; a series of paddle blades having horizontal parallel axes lying in a plane above the upper surface of the etching liquid in the tank when filled to its working level and adapted on being revolved to splash the etching liquid about the tank; upstanding baffles between the said paddle blades adapted to guide the splashed etching liquid in a generally vertical direction; a removable cover adapted to form a closure for the top of the tank so as to prevent escape of etching liquid on being splashed in the tank; a work holder plate above the baffles below the underside of the cover; motor means on the top of the cover adapted to impart to the work holder simultaneously a translatory and rotational motion in a horizontal plane.

U.S. Pat. No. 1,383,010 relates to an etching machine the combination with a tank for the etching liquid having a support for the plate to be etched of a circular member haying continuous grooves extending around its periphery adapted to rotate in constant contact with the etching liquid and project said liquid against said plate.

EP-448870 relates to etchant baths for dissolution of metals and to a system and process for regenerating alkaline ammoniacal etchant solutions which have reached a degree of reduced etching ability, particularly as a consequence of increased concentration therein of etched metals.

U.S. Pat. No. 3,524,457 directed to an improvement in etching machines suitable for powderless etching of zinc or magnesium.

Till date, the existing etchant system requires directly or indirectly pumps or any machine force or auto dosing system through spray for etching process. The present invention provides continuous copper etching system in manufacturing of PCBs without pump or any machine force for flowing of etchant.

### Few Important Criteria for the Etching System

Etching Time: When the plate is kept in the bath for less time, there is also risk of copper remaining in the open or exposed space which may lead to short-circuits at close premise. Therefore, careful observation and controlled timing of etching is required. The less effective an etchant, it takes longer time to remove the copper from the plate or more quantity is required for etching.

Thickness of PCB: An appropriate copper thickness in a PCB is very necessary to obtain desired results. Copper thickness of PCBs can be specified as units of length (in micrometers or mils) but is often specified as weight of copper per area (in ounce per square foot) which is easier to measure. One ounce per square foot is 1.344 mils or 34 micrometres thickness.

The printed circuit board industry defines heavy copper as layers exceeding three ounces of copper, or approximately 0.0042 inches (4.2 mils, 105 μm) thick. The thicker the copper layer, the current carrying capacity of the PCB increases as well as resistance to thermal strains also increases. IPC 2152 is a standard for determining current-carrying capacity of printed circuit board traces.

On the common FR-4 substrates, 1 oz copper (35 μm) is the usual, most common thickness; 2 oz (70 μm) and 0.5 oz (18 μm) thickness is often an option. Less common are 12 and 105 μm, 9 μm is sometimes available on some substrates. Flexible substrates typically have thinner metallization; 18 and 35 μm seem to be common, with 9 and 70 μm sometimes available. Aluminium or metal-core boards for high power devices commonly use thicker copper; 35 μm is usual but also 140 and 400 μm can be encountered.

Disposal of Etchant: Further, gradually the used etchant becomes saturated and less effective and different etchants have different capacities for copper, with some as high as 150 grams of copper per litre of solution. This solution or etchant can be regenerated by recovering copper from etchant, mostly, however, due care is required during disposal of used etchant as it is corrosive, toxic and contains metal and other harmful contents.

Undercut: “Undercut” or removal of copper which was necessary to be preserved on PCB is one of the major drawback of chemical etching. Undercut occurs when etchant attacks the thin edge of copper under the resist or cover; this can reduce conductor widths and cause open-circuits and deteriorate the quality of PCB. Undercut is more when plate is dipped for longer time in etching bath.

Thus, the ideal system for etching copper in manufacturing of PCBs should have some properties such as high etch rate, minimum undercut, high dissolved copper capacity, easy control, economic regeneration of waste etchant and copper recovery. There is need to develop advance etching system having following characteristics during manufacturing of PCB:
High rate & Speedy copper etching from PCB,
Stable and uniform Etching,
Zero undercut,
Zero residue copper,
Non-corrosive surface on PCB,
Environmental Safe (Non-Hazardous),
Economic (Cheaper cost).

### OBJECT OF INVENTION

It is an object of the present invention to overcome the above described disadvantages of the conventional etching system or apparatus for etching copper in manufacturing of PCBs.

The main object of the invention to provide highly efficient, economical, environment friendly continuous etching system for etching copper in manufacturing PCBs leads to yield of high accuracy PCB results.

### SUMMARY OF THE INVENTION

According to the present invention, there is provided continuous etching system for etching copper in manufacturing PCBs comprising a conveyer for conveying PCBs, tanks containing fresh etchant and spent, valves for controlling and adjusting continuous dripping of fresh etchant on the PCB.

### DESCRIPTION OF FIGURES

FIG. 1: Layout of Conveyor Etching Machine/Chamber of the present Invention

### DETAILED DESCRIPTION OF THE INVENTION

The present invention meets the above mentioned and other needs by providing continuous etching system for etching copper in manufacturing PCBs.

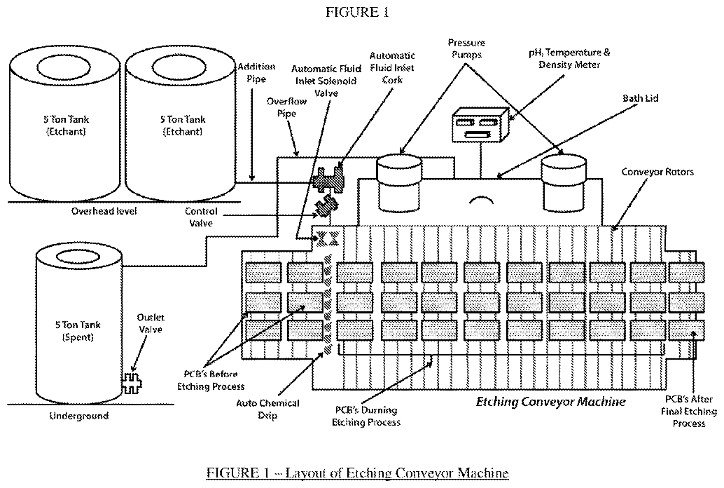

Now to the drawing (FIG. 1), there is shown an embodiment of a continuous etching system for etching copper in manufacturing PCBs according to the present invention.

The continuous etching system comprising a conveyer for conveying PCBs, tanks containing fresh etchant and spent, valves for controlling and adjusting continuous dripping of fresh etchant on the PCBs. The said tanks are made of a corrosion resistant material PVC.

Firstly, the continuous etching system of the present invention, the series of PVC chemical tank(s) are installed in the premise at an overhead level from the etching conveyor machine/chamber, which will contain fresh etchant. Preferably, the fresh etchant is an aqueous alkaline copper etch accelerating additive solution in the primary ammonia based copper etching solution.

The fresh etchant is stored in the overhead level tank which is connected via PVC pipes directly to the etching conveyor machine/chamber. This fresh etchant is transported directly into the etching conveyor machine/chamber by gravity as the tanks are kept at an overhead level.

Then, the series of PVC chemical tanks are installed in the premise at an underground level from the etching conveyor machine/chamber which contains spent/used etchant. The underground tank is connected via PVC pipes at such level through which the chemical automatically flows out without and pump or any machine force.

At the point where the PVC pipes from the overhead level fresh etchant tanks connected to the etching conveyor machine/chamber, a thin high profile 0.5 mm CPVC pipe is installed at the entrance of the etching conveyor machine/chamber. This pipe is carved/made of 0.5/“X” mm diameter holes at an ‘X’ distance throughout the pipe. This pipe is called the CPVC Continuous Drip Addition pipe.

One on-off valve is connected at front of the CPVC Continuous Drip Addition pipe. This valve can control the chemical etchant in/out from the overhead pipe to the CPVC Continuous Drip Addition pipe.

One Automatic fluid inlet valve is installed adjacent to the one on-oft valve for controlling the speed of chemical coming from the overhead tank to the etching conveyor machine chamber. This speed control valve can control the speed of CPVC Continuous Drip Addition pipe as per the copper thickness of the PCB being etched. The speed can be controlled as per necessary parameters of the current ongoing etching PCB. The CPVC Continuous Drip Addition pipe is kept always open/on with speed control valve only working as per PCB needs.

The etchant outlet pipe is kept at a level at the etching conveyor machine/chamber from which only the considerable or the unused or the etchant, which is not capable to etch copper anymore, flushes out of the etching bath drip by drip. This pipe is directly connected to the underground tanks installed in the premise which will only contain highly copper rich spent etchant with very minimal fresh ammonia and chloride concentrations, which can be very beneficial and easy in copper extraction process for waste management industries.

This system can automatically balance the copper density of the bath as the CPVC Continuous Drip Addition pipe continuously adds fresh etchant and the fluid overflow pipe continuously outlets spent etchant the density is optimum maintained throughout the process and through which PCB etching can be attained accurately less than 1 mil.

Due to the CPVC Continuous Drip Addition pipe, there is no issue of copper under etching problem or copper over etching problem.

This continuous etching system of the present invention overcomes all the major drawbacks arising during bare board testing process due to etching at zero stake, which can cause no rejection of PCB at final stage.

The continuous etching system of the present invention also provides solution of problem like no copper spot issue while etching process during manufacturing PCBs.

If there is no problem like under and over etching of copper during etching, sometimes there are some other problems of extra additional spots on the etched surface of the PCB which has to be removed.

On implementation of the continuous etching system of the present invention system provides permanent solution of this problem by using combination of the fresh etchant with exact chloride concentrations, exact ammonia concentrations and exact copper concentration with suitable parameter which results with no spots or under or over issue.

The continuous etching system of the present invention also eliminates ammonia smell whilst usage and feed of etching in the conveyor etching machine/chamber. As both tanks of etchant input and output of spent are connected by high quality PVC pipes. Another advantage of these pipes leads to not only protect leakage but also protect operators, workers and factory staff from irritating ammonia odor or ammonia fumes emission during etching. By this way, the continuous etching system of the present invention results in zero environment pollution which are prominent in currently used etching system.

The continuous etching system of the present invention also contributes in zero drum movement in the plant floor as the etchant is transported through fixed pipes structure which in beneficiary can make the conveyor bath surroundings and plant floor neat and clean. There is no extra drum provisions needed for emergency addition or any other activity of etchant addition, since everything is carried out automatically by gravity.

As continuous etchant is added and continuous etchant is removed in the continuous etching system of the present invention, exceptionally fast copper etching can be carried out in the conveyor bath rather than comparing a conveyor equipped with auto dosing fitted or manual feed both. Thus, the continuous etching system of the present invention leads to super-fast production speeds with far superior etching results.

In the continuous etching system of the present invention, the fresh etchant has to be emptied into the overhead level directly from the tanker and the underground etchant spent is directly filled out to the empty tanker or waste management services from the tanks installed directly out of the plant from the company premises without hampering any plant movement and causing plant production without any hindrance.

In case of Etching carried out with the auto dosing, the etching conveyor machine has to be stopped and reworked to maintain all etching optimum parameters. Then, the etching process again has to start from initial level for manufacturing PCB. Such type of re-feed and reworked many times again and again in a day. This process also becomes a headache for the etching operator as the auto dosing has to maintain all parameters like pH, density and temperature.

Through-out the continuous etching system of the present invention, all the parameters are never disturbed as the fresh etchant is continuously added by drip-by-drip and used spent etchant is continuously collected out. Moreover, the etching system of the present invention will not be stopped due to parameters remain unchanged. It is very easy to use this etchant system of the present invention for any operator as he has to just turn off the chemical inlet valve and turn off the etchant conveyor machine/chamber. When the operator will resume the work, then he can initiate the work by switching on the etchant conveyor machine/chamber without maintaining any parameters, and by turning on the fresh chemical inlet valve so that the chemical etchant starts entering through the continuous drip pipe and the process starts immediately with zero rework or re-feed with zero under etching or zero over etching. This is the main and the key benefit of this etching system of the present invention which is very necessary for all PCB manufacturers worldwide for faster and efficient etching.

This etching system of the present invention can also provide zero rejection of PCB, Zero under etching of PCB, Zero over etching of PCB, Zero production hindrance due to etching parameters, Zero drum movement on plant floor and Zero ammonia odor whilst usage.

In the above disclosure, it is understood that terms such as “a”, “an”, “the”, and like are words used for convenience and are not to be constructed as limiting terms. Although the present invention has been described in considerable detail with reference to certain preferred embodiments thereof, other versions are possible. Moreover, it will be understood that the illustrations are for the purpose describing exemplary embodiment of the invention and the same do not limit the scope of the present invention.

1. An Etching System for copper etching in manufacturing of Printed Circuit Boards (PCB) comprises
a. an etching conveyer machine or chamber which comprises a plurality of conveyer rotors
b. Tank(s) containing fresh Etchant set at an overhead level from the said etching machine/chamber
c. Tank(s) containing spent or used etchant set at an underground level from the said etching machine/chamber
d. Pipes which connect both tanks with the said etching conveyor machine/chamber
e. Valves.

2. The Etching System according to claim 1, wherein the tank is made of a corrosion resistant material.

3. The Etching System according to claim 2, wherein the corrosion resistant material is PVC.

4. The Etching System according to claim 1, wherein the fresh etchant is an aqueous alkaline copper etch accelerating additive solution in the primary ammonia based copper etching solution.

5. The Etching System according to claim 1, wherein the fresh etchant is transported directly into the etching conveyor machine/chamber by gravity as the tanks are kept at an overhead level.

6. The Etching System according to claim 1, wherein the underground tank and pipe fitting attached at a level at through which the considerable spent/used etchant collected in tank.

7. The Etching System according to claim 1, wherein the tank containing the fresh etchant is connected via PVC pipes directly to the etching conveyor machine/chamber.

8. The Etching System according to claim 7, wherein the pipe is the CPVC Continuous Drip Addition pipe.

9. The Etching System according to claim 1, wherein the tank containing spent is connected via PVC pipes directly to the etching conveyor machine/chamber.

10. The Etching System according to claim 9, wherein the pipe is the Etchant Outlet pipe.

11. The Etching System according to claim 1, wherein the one on-off valve is connected at front of the CPVC Continuous Drip Addition pipe.

12. The Etching System according to claim 11, wherein control the chemical in/out from the overhead pipe to the CPVC Continuous Drip Addition pipe.

13. The Etching System according to claim 1, wherein the climatic fluid inlet valve adjacent to the one on-off valve.

14. The Etching System according to claim 13, wherein the Automatic fluid inlet valve controls the speed of chemical supplied from the overhead tank to the etch chamber.

15. The Etching System according to claim 13, wherein the Automatic fluid inlet valve controls the speed of CPVC Continuous Drip Addition pipe as per the copper thickness of the PCB being etched.
